(19) United States
(12) Patent Application Publication
(10) Pub. No.: US 2012/0005887 A1
(43) Pub. Date: Jan. 12, 2012

(54) CORELESS SUBSTRATE, METHOD OF MANUFACTURING SAME, AND PACKAGE FOR MICROELECTRONIC DEVICE INCORPORATING SAME

(76) Inventors: Russell Mortensen, Chandler, AZ (US); Mahadevan Suryakumar, Gilbert, AZ (US)

(21) Appl. No.: 13/238,009

(22) Filed: Sep. 21, 2011

Related U.S. Application Data
(62) Division of application No. 12/284,542, filed on Sep. 22, 2008.

(51) Int. Cl. H05K 3/00

(52) U.S. Cl. 29/829

(57) ABSTRACT

A coreless substrate includes a stiffener material (110, 210, 620) having a plated via (120, 320) formed therein, an electrically insulating material (130, 230, 830) above the stiffener material, and an electrically conductive material (140, 240, 840) in the electrically insulating layer. In the same or another embodiment, a package for a microelectronic device includes a stiffener material layer (115, 215, 615) having plated vias (120, 320) formed therein and further having a recess (118, 218) therein, build-up layers (150, 350, 850) over the stiffener material layer, and a die (370) attached over the build-up layers. The stiffener material layer and the build-up layers form a coreless substrate (100, 380, 910, 920) of the package. The coreless substrate has a surface (381), and the die covers less than all of the surface of the coreless substrate such that the surface has at least one exposed region (382).

### CLAIM OF PRIORITY

This application is a divisional of U.S. patent application Ser. No. 12/284,542, now abandoned, which was filed on Sep. 22, 2008.

### FIELD OF THE INVENTION

The disclosed embodiments of the invention relate generally to packages for microelectronic devices, and relate more particularly to coreless substrates for such packages as well as to methods for manufacturing them.

### BACKGROUND OF THE INVENTION

Microelectronic device performance frequently depends upon, or is enhanced by, the use of capacitors. The location of such capacitors in relation to the microelectronic device can also be an important parameter affecting performance. Thus, for example, many microelectronic packages are outfitted with “land side” and/or “die side” capacitors: capacitors that are located, respectively, on the land side (sometimes called the bottom side) or the die side (sometimes called the top side) of the package. In addition to capacitors, it is also desirable to place test pads on the package for the purpose of debugging and of testing electrical performance and/or the functionality of the part.

However, existing microelectronic packages are characterized by large top side keep out zones, i.e., package areas that, because of processing or design requirements, cannot accept capacitors, test pads, or any other components. Often the keep out zones are occupied by an overmold or a stiffening material that is used to strengthen the package. This is especially true for packages having coreless substrates which, because they lack the stability that a substrate core would provide, must be strengthened by other means in order to avoid warpage and other deformation that would, for example, prevent the package from being reflowed to a motherboard. In this and similar scenarios top side test pads and die side capacitors cannot be used unless the package form factor grows to make additional space for them, as happens, for example, when test pads are taken to bottom side balls or lands. Such larger package form factors are themselves an undesirable result but also of concern is the fact that bottom side test pads become inaccessible once the package is reflowed to a motherboard or is otherwise permanently attached to a next-level component. Furthermore, as device and package sizes shrink, thereby reducing package standoffs, even the capacitors placed in a bottom side package cavity are affected in that low profile components such as XLP (extremely low profile) capacitors and advanced land side capacitors (ALSCs) must be used. Among other drawbacks, these have reduced capacitance values and are very expensive.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a coreless substrate according to an embodiment of the invention;

FIG. 2 is a bottom plan view of a package for a microelectronic device according to an embodiment of the invention;

FIG. 3 is a cross-sectional view of the package of FIG. 2 according to an embodiment of the invention;

FIG. 4 is a flowchart illustrating a method of manufacturing a coreless substrate according to an embodiment of the invention; and

FIGS. 5-9 are cross-sectional views of a coreless substrate shown at various particular points in its manufacturing process, according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements, while similar reference numerals may, but do not necessarily, denote similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a coreless substrate comprises a stiffener material having a plated via formed therein, an electrically insulating material above the stiffener material, and an electrically conductive material in the electrically insulating material. In the same or another embodiment, a package for a microelectronic device comprises a stiffener material layer having plated vias formed therein and further having a recess therein, build-up layers over the stiffener material layer, and a die attached over the build-up layers. The stiffener material layer and the build-up layers form a coreless substrate of the package. The coreless substrate has a surface, and the die covers less than all of the surface of the coreless substrate such that the surface has at least one exposed region.

Embodiments of the invention allow for the placement of standard land side capacitors in a substrate cavity for better power delivery performance. Furthermore, embodiments of the invention provide for smaller coreless package form factors due to the removal of top side keep out zones. The removal of such keep out zones provides a bare substrate top side on which to place discrete components and/or test pads that would otherwise be covered up by overmold or stiffeners. These substrates can be stiff enough to either be unit or strip processed, leading to reductions in both assembly cost and package form factor.

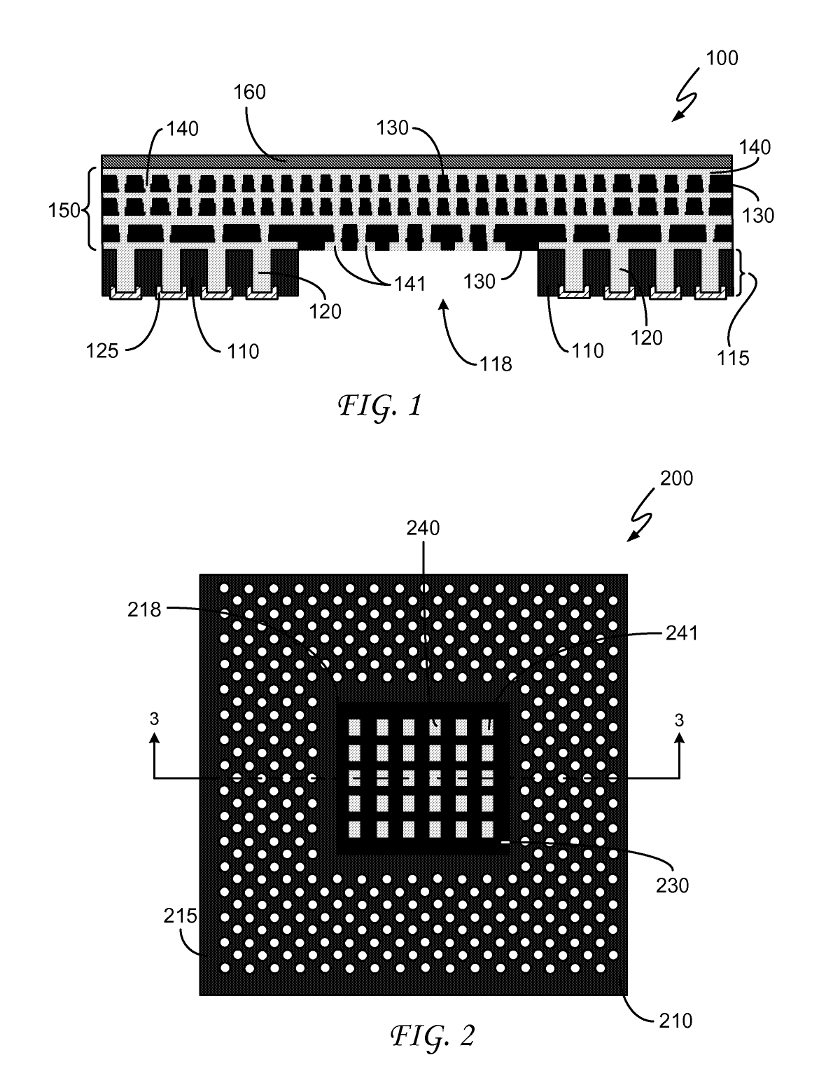

Referring now to the drawings, FIG. 1 is a cross-sectional view of a coreless substrate 100 according to an embodiment of the invention. As illustrated in FIG. 1, coreless substrate 100 comprises a stiffener material 110 having a plated via 120 formed therein. Plated via 120 terminates in an electrically conductive pad 125, such as a copper pad or the like, in the illustrated embodiment, stiffener material 110 forms, or is located in, a stiffener material layer 115 of coreless substrate 100 and coreless substrate 100 further comprises a recess 118 in stiffener material layer 115. As an example, stiffener material 110 can be mold compound or the like. In at least one embodiment, stiffener material 110 is selected for its ability to release or be removed easily from the build-up layers that are introduced below. Coreless substrate 100 further comprises electrically insulating material 130 above stiffener material 110 and electrically conductive material 140 including lands 141 in electrically insulating material 130. Together, electrically insulating material 130 and electrically conductive material 140 form build-up layers 150.

As an example, plated via 120 can be lined (plated) with copper or another suitable electrically conductive material. Electrically conductive material 140 could also be copper or the like. Coreless substrate 100 further comprises an electrically insulating layer 160 over electrically insulating material 130. As an example, electrically insulating layer 160 can be a soldermask layer.

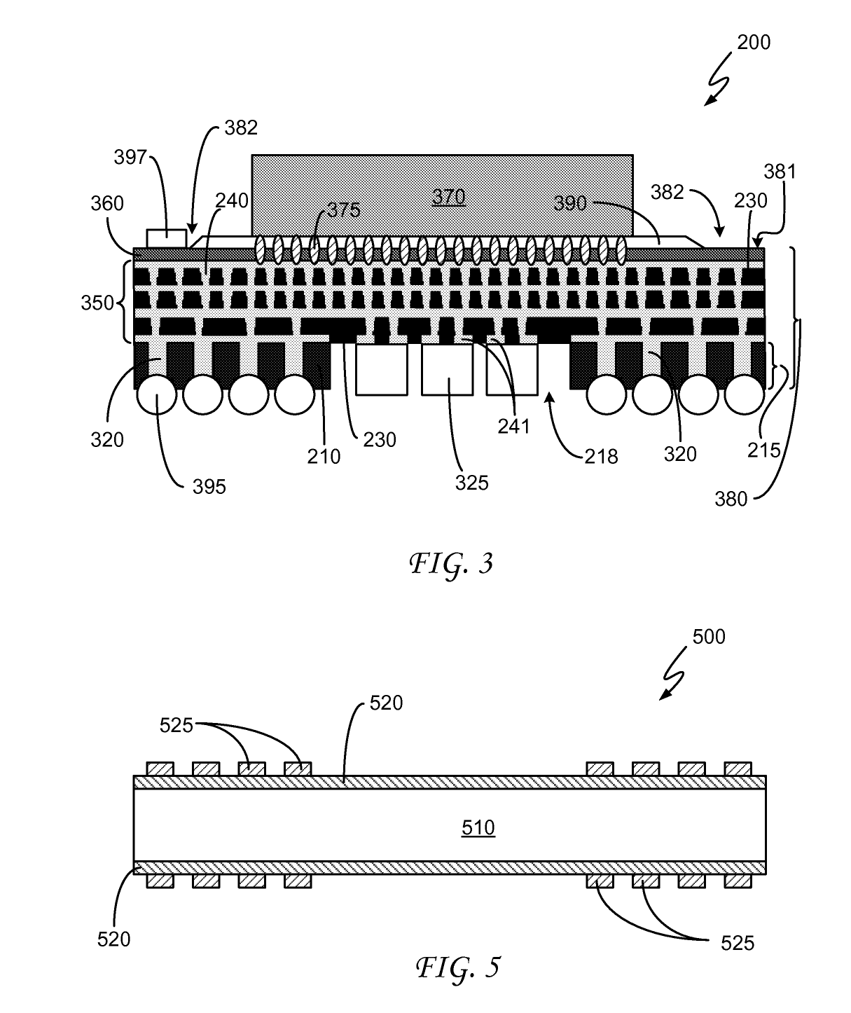

FIG. 2 is a bottom plan view of a package 200 for a microelectronic device according to an embodiment of the invention. FIG. 3 is a cross-sectional view of package 200 taken along a line 3-3 of FIG. 2. As illustrated in FIGS. 2 and 3, package 200 comprises a stiffener material layer 215 containing stiffener material 210 and having plated vias 320 formed therein and further having a recess 218 therein. Build-up layers 350 are located over stiffener material layer 215 and comprise electrically insulating material 230 and electrically conductive material 240. Electrically conductive material 240 includes lands 241. An electrically insulating layer 360 is over build-up layers 350. As an example, stiffener material 210, stiffener material layer 215, recess 218, plated vias 320, electrically insulating material 230, electrically conductive material 240, lands 241, build-up layer 350, and electrically insulating layer 360 can be similar to, respectively, stiffener material 110, stiffener material layer 115, recess 118, plated vias 120, electrically insulating material 130, electrically conductive material 140, lands 141, build-up layer 150, and electrically insulating layer 160, all of which are shown in FIG. 1.

Package 200 further comprises a die 370 attached over build-up layers 350. As illustrated, stiffener material layer 215, build-up layers 350, and electrically insulating layer 360 form a coreless substrate 380 of package 200. Coreless substrate 380 has a surface 381, and die 370 covers less than all of surface 381 of coreless substrate 380 such that surface 381 has at least one exposed region 382. As explained above, exposed region 382 is made possible because the stiffener material on the land side of the package provides the package with sufficient stiffness and strength such that no additional stiffener, overmold, or other strengthening materials are needed on the die side of the package. This leaves a certain portion of the substrate surface exposed, open, and available for the placement of one or more desired components, as illustrated.

Die 370 is attached to coreless substrate 380 with an epoxy 390 or a similar adhesive material. Solder bumps 375 electrically connect die 370 to electrically conductive material 240, Solder balls 395 provide a means to attach package 200 to a next-level component such as a motherboard or the like.

In the illustrated embodiment, package 200 comprises capacitors 325 in recess 218. As explained above, the configuration of package 200 is such that capacitors 325 may be standard or low profile capacitors rather than ALSCs or XLP capacitors, and their placement in recess 218 enhances the power delivery performance of package 200. The standard or low profile capacitors are also less expensive than ALSCs or XLP capacitors. It should be noted that in the interest of clarity, capacitors 325 are omitted from FIG. 2 even though they would normally be visible adjacent to lands 241 in the bottom plan view. Thus capacitors 325 are only depicted in FIG. 3.

FIG. 3 also shows a component 397 in exposed region 382 of surface 381 of coreless substrate 380. As an example, component 397 may be a capacitor, a test pad, or the like. In a non-illustrated embodiment, package 200 comprises both a capacitor (or other passive component) and a test pad or some other combination or number of such components in exposed region 382. As an example, the availability of a test pad on surface 381 greatly facilitates device testing after package 200 has been attached to a motherboard or other next level component (at which time land side test pads are no longer accessible).

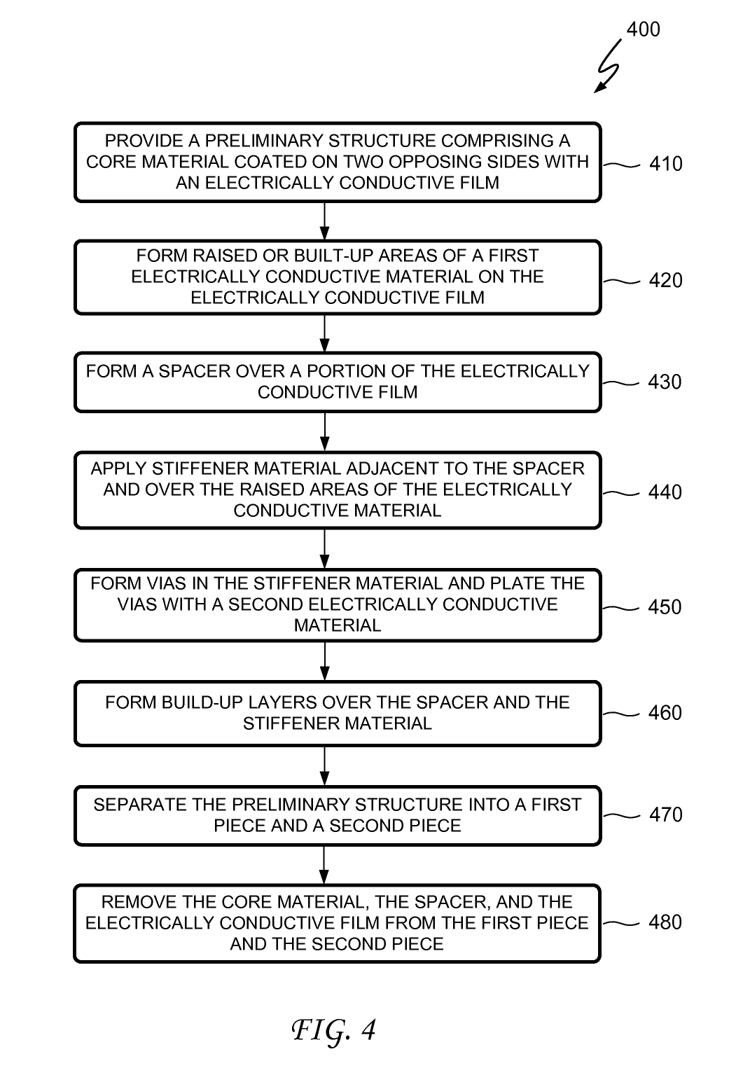

FIG. 4 is a flowchart illustrating a method 400 of manufacturing a coreless substrate according to an embodiment of the invention. As an example, method 400 may result in the formation of a coreless substrate that is similar to coreless substrate 100 that is shown in FIG. 1. Method 400 is further described with reference to FIGS. 5-9, each of which are cross-sectional views of the coreless substrate at various particular paints in its manufacturing process according to an embodiment of the invention.

A step 410 of method 400 is to provide a preliminary structure comprising a core material coated on two opposing sides with an electrically conductive film. As an example, the preliminary structure can be similar to a preliminary structure 500 that is first shown in FIG. 5. As another example, the core material can be similar to a core material 510 and the electrically conductive film can be similar to an electrically conductive film 520, both of which are also first shown in FIG. 5.

As illustrated in FIG. 5, and as mentioned above, preliminary structure 500 comprises core material 510 that is coated with electrically conductive film 520 on its top and bottom surfaces. As an example, electrically conductive film 520 can comprise a copper foil or the like.

A step 420 of method 400 is to form raised or built-up areas of a first electrically conductive material on the electrically conductive film. In one embodiment, the first electrically conductive material can be copper or a similar material. Accordingly, the raised areas of electrically conductive material can be similar to copper pads 525 that are first shown in FIG. 5, though it should be understood that, as implied above, other materials may alternatively be used in place of copper. As an example, copper pads 525 can be similar to electrically conductive pad 125 that is shown in FIG. 1. In one embodiment, copper pads 525 are formed by electroplating copper areas onto the copper foil.

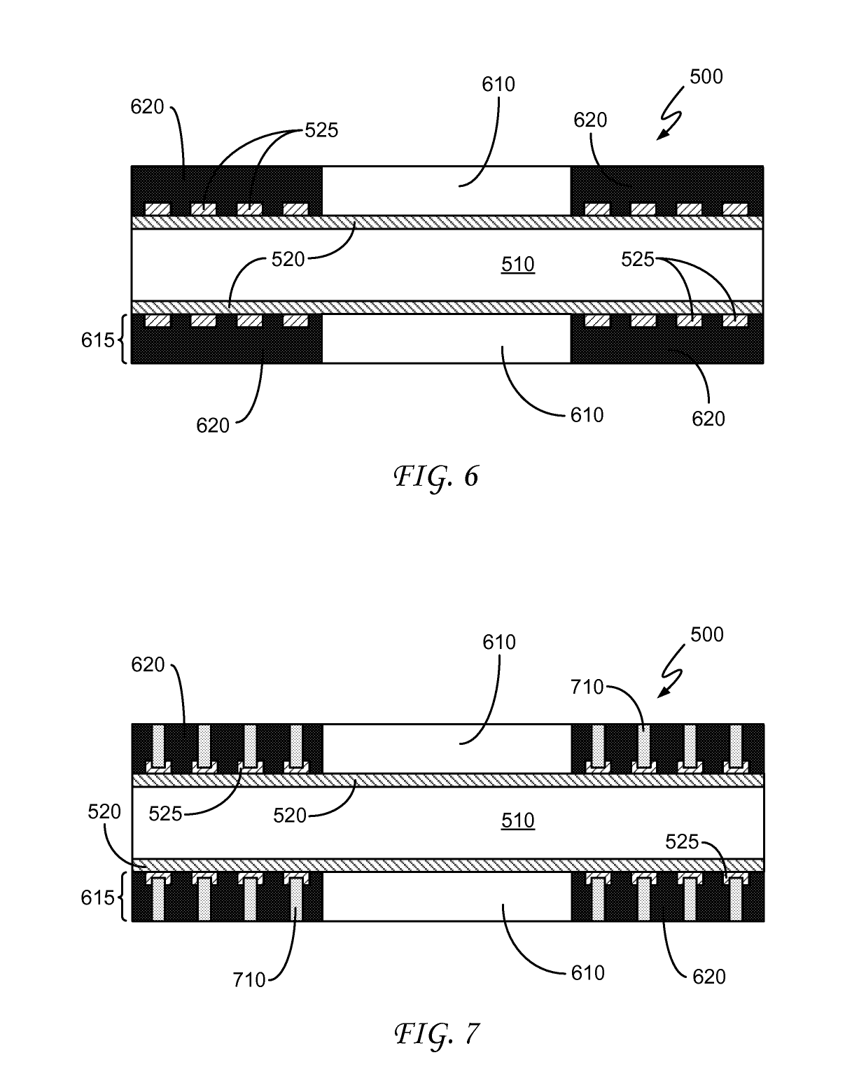

A step 430 of method 400 is to form a spacer over a portion of the electrically conductive film. As an example, the spacer can be similar to spacers 610 that are first shown in FIG. 6. As another example, spacer 610 can comprise a plastic molded spacer or a metal slug spacer, In one embodiment, step 430 comprises compression molding the spacer or placing a prefabricated spacer in the proper position. As the following discussion will make clear, the removal of the spacer in a subsequent step creates a cavity in the coreless substrate suitable for receiving capacitors. These land side capacitors may enhance the power delivery and other performance of the package, as mentioned above.

A step 440 of method 400 is to apply stiffener material adjacent to the spacer and over the raised areas of the electrically conductive material. As an example, the stiffener material can be similar to a stiffener material 620 that is first shown in FIG. 6. As another example, stiffener material 620 can comprise mold compound. In the illustrated embodiment, stiffener material 620 is located in a stiffener material layer 615. As an example, stiffener material layer 615 can be similar to stiffener material layer 115 that is shown in FIG. 1.

It should be understood that in some embodiments of method 400, steps 430 and 440 can be performed in reverse order, or combined into a single step. That is, in some embodiments the stiffener material may be applied before (or at the same time as) the spacer.

A step 450 of method 400 is to form vias in the stiffener material and plate the vias with a second electrically conductive material. In one embodiment, the second electrically conductive material is the same as or similar to the first electrically conductive material, As an example, the vias can be similar to vias 710 that are first shown in FIG. 7. In one embodiment, step 450 comprises drilling the vias with a laser using any suitable one of the laser-assisted material removal processes that are known in the art. Mechanical drilling processes could also be used.

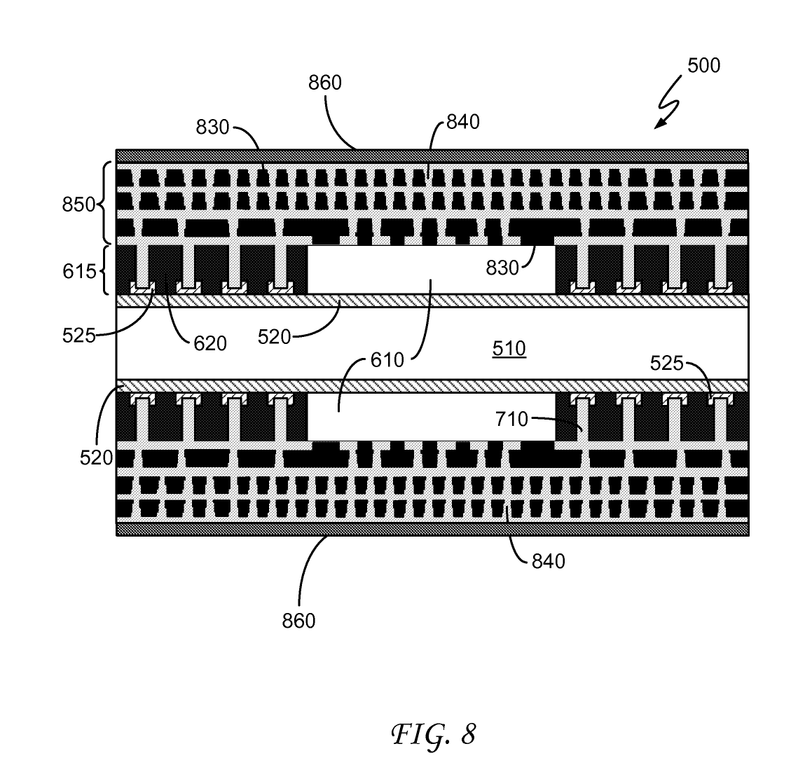

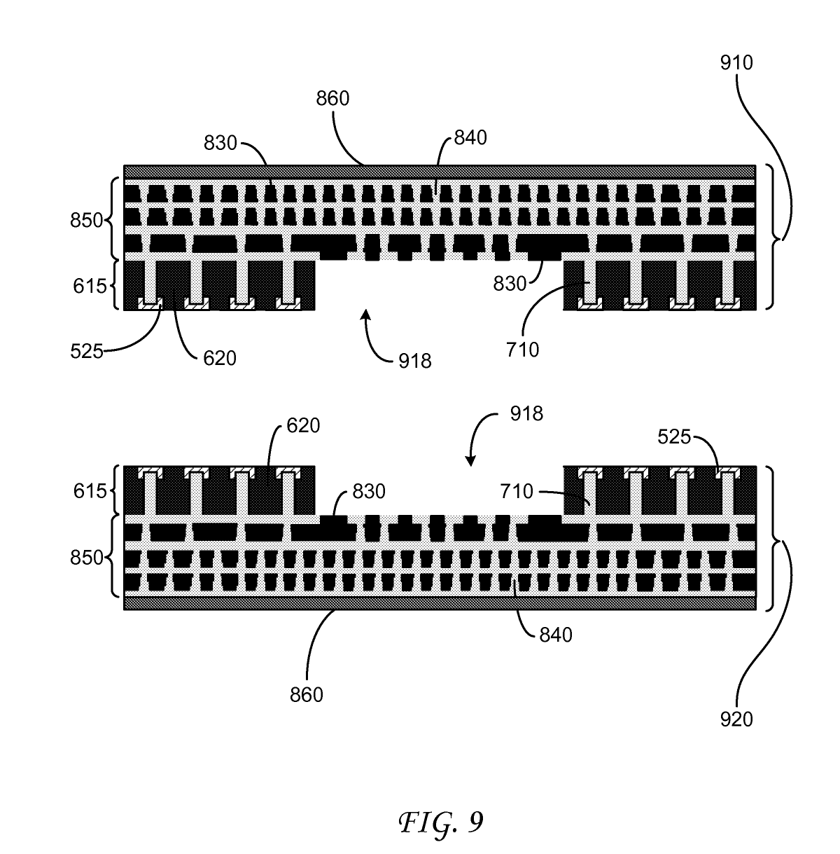

A step 460 of method 400 is to form build-up layers over the spacer and the stiffener material. As an example, the build-up layers can be similar to build-up layers 150 that are first shown in FIG. 1. As another example, the build-up layers can be similar to build-up layers 850 that are first shown in FIG. 8. In one embodiment, step 460 or another step can include the formation of an electrically insulating layer over (or as an uppermost layer of) the build-up layers. As an example, the electrically insulating layer can be similar to electrically insulating layer 160 that is shown in FIG. 1. As another example, the electrically insulating layer can be similar to an electrically insulating layer 860 that is first shown in FIG. 8.

As illustrated in FIG. 8, following the performance of step 460, preliminary structure 500 comprises electrically insulating material 830 and electrically conductive material 840. As another example, electrically insulating material 830 and electrically conductive material 840 can be similar to, respectively, electrically insulating material 130 and electrically conductive material 140, both of which are shown in FIG. 1.

A step 470 of method 400 is to separate the preliminary structure into a first piece and a second piece. After some further processing, discussed below, the first piece and the second piece become completed coreless substrates. Accordingly, in the illustrated embodiment, method 400 turns each preliminary structure into two separate coreless substrates. Step 470 may be accomplished using any suitable singulation technique.

A step 480 of method 400 is to remove the core material, spacer, and the electrically conductive film from the first piece and the second piece. A result of the performance of step 480 is shown in FIG. 9. As illustrated, preliminary structure 500 has been turned into two substantially identical coreless substrates 910 and 920, each of which may be similar to coreless substrate 100 of FIG. 1. In one embodiment, step 480 comprises etching the core material, the spacer, and the electrically conductive film using an appropriate etch technique.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the coreless substrates, the microelectronic packages, and the related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of manufacturing a coreless substrate, the method comprising:
providing a preliminary structure comprising a core material coated on two opposing sides with an electrically conductive film;
forming raised areas of a first electrically conductive material on the electrically conductive film;
forming a spacer over a portion of the electrically conductive film;
applying stiffener material adjacent to the spacer and over the raised areas of the first electrically conductive material;
forming vias in the stiffener material and plating the vias with a second electrically conductive material;
forming build-up layers over the spacer and the stiffener material;
separating the preliminary structure into a first piece and a second piece; and
removing the core material, the spacer, and the electrically conductive film from the first piece and the second piece.

2. The method of claim 1 wherein:
providing the preliminary structure comprises providing the core material coated on two opposing sides with copper foil.

3. The method of claim 2 wherein:
forming raised areas of the first electrically conductive material comprises electroplating copper regions onto the copper foil.

4. The method of claim 1 wherein:
forming the spacer comprises forming a plastic molded spacer or a metal slug spacer.

5. The method of claim 1 wherein:
forming vias in the stiffener material comprises drilling the vias with a laser.

6. The method of claim I wherein:
separating the preliminary structure into the first piece and the second piece comprises cutting through the core material.

7. The method of claim 1 wherein:
removing the core material, the spacer, and the electrically conductive film comprises etching the core material, the spacer, and the electrically conductive film using a wet etch or a dry etch.
